(19) United States
(12) Patent Application Publication
(10) Pub. No.: US 2016/0268421 A1
(43) Pub. Date: Sep. 15, 2016

(54) SEMICONDUCTOR DEVICE

(71) Applicant: KABUSHIKI KAISHA TOSHIBA, Tokyo (JP)

(72) Inventor: Hitoshi SHINOHARA, Katsushika Tokyo (JP)

(21) Appl. No.: 14/836,721

(22) Filed: Aug. 26, 2015

(30) Foreign Application Priority Data
Mar. 11, 2015 (JP) 2015-048888

(51) Int. Cl. H01L 29/78; H01L 29/417; H01L 29/06; H01L 29/10; H01L 29/08; H01L 23/48; H01L 29/739; H01L 23/00

(52) U.S. Cl. CPC H01L 29/7813; H01L 29/7397; H01L 29/41741; H01L 29/41766; H01L 24/13; H01L 29/1095; H01L 29/0882; H01L 29/0865; H01L 23/481; H01L 29/0696; H01L 2224/13014; H01L 2224/13016; H01L 2924/13091; H01L 2924/13055

(57) ABSTRACT

A semiconductor device includes a semiconductor substrate having a first surface and a second surface opposite to the first surface, a first region of a first conductivity type provided along the first surface selectively on a second region of a second conductivity type formed along the first surface, and a third region of a first conductivity type between the second region and the second surface. The semiconductor device also includes a gate electrode adjacent to the second region. First, second, and third electrode pads are formed along the second surface. The first pad is electrically connected by a first via through the substrate to first region. The third electrode pad is electrically connected by a second via through the substrate to the gate electrode.

### CROSS-REFERENCE TO RELATED APPLICATION

This application is based upon and claims the benefit of priority from Japanese Patent Application No. 2015-048888, filed Mar. 11, 2015, the entire contents of which are incorporated herein by reference.

### FIELD

Embodiments described herein relate generally to a semiconductor device.

### BACKGROUND

In a vertical type MOSFET (Metal Oxide Semiconductor Field Effect Transistor) or a vertical type IGBT (Insulated Gate Bipolar) having the MOS (Metal Oxide Semiconductor) structure, a dead space where transistors may not be disposed is directly below a gate pad used for applying a gate voltage. In a device having a small chip size such as a small signal MOSFET, the gate pad occupies a particularly large percentage of the total area of the device. Accordingly, this dead space limits the number of transistors which may be included in the device, and the ability to provide a reduction of ON resistance without increasing the size of the device (chip size).

### DESCRIPTION OF THE DRAWINGS

FIG. 1A and FIG. 1B are schematic plan views of a semiconductor device according to a first embodiment.

FIG. 2A and FIG. 2B are schematic cross-sectional views of the semiconductor device according to the first embodiment.

FIG. 3 is a schematic cross-sectional view of an element region of the semiconductor device according to the first embodiment.

FIG. 4A and FIG. 4B are schematic plan views of a semiconductor device according to a comparative embodiment.

FIG. 5 is an explanatory view showing the manner of operation and advantageous effects of the semiconductor device according to the first embodiment.

FIG. 6A and FIG. 6B are schematic plan views of a semiconductor device according to a second embodiment.

### DETAILED DESCRIPTION

According to an example embodiment, there is provided a semiconductor device where an ON resistance may be reduced.

In general, according to one embodiment, a semiconductor device includes a semiconductor substrate having a first surface and a second surface opposite to the first surface. The substrate includes a first region of a first conductivity type provided along the first surface, a second region of a second conductivity type provided along the first surface, the first region being selectively provided in the second region, and a third region of the first conductivity type between the second semiconductor region and the second surface. A gate electrode is disposed adjacent to second region through a gate insulation film. For example, the gate electrode may be disposed in a trench extending into the substrate from the first surface. A first electrode pad is disposed on the second surface and electrically insulated from the third region. A second electrode pad is disposed on the second surface and electrically connected to the third region. A third electrode pad is disposed on the second surface and electrically insulated from the third region and electrically connected to the gate electrode. A first via extends through the semiconductor substrate from the second surface to the first surface for electrically connecting the first region to the first electrode pad, and a second via extends through the semiconductor substrate from the second surface to the first surface for electrically connecting the gate electrode to the third electrode pad.

Hereinafter, exemplary embodiments are explained by reference to drawings. In the explanation made hereinafter, identical parts or the like are given the same symbols, and the explanation of such parts or the like having been explained once is omitted when appropriate. In the following example embodiments, the explanation is made by taking a case where a first conductivity type is an n-type and a second conductivity type is a p-type.

In this disclosure, the descriptions “n⁺-type”, “n-type”, and “n⁻-type” mean that a concentration of n-type dopant is lowered in that order. Likewise, the descriptions “p⁺-type”, “p-type”, “p⁻-type” mean that a concentration of p-type dopant is lowered in that order as well.

An n-type dopant is phosphorus (P) or arsenic (As), for example. A p-type dopant is boron (B), for example.

### First Embodiment

The semiconductor device according to this first embodiment includes: a semiconductor substrate having a first surface and a second surface disposed on a side opposite to the first surface, a first region of a first conductivity type formed on the first surface, a second region of a second conductivity type formed on a second surface side of the first region, and a third region of a first conductivity type formed on a second surface side of the second region; a gate electrode; a gate insulation film formed between the gate electrode and the second region; a first electrode formed on a second surface side of the semiconductor substrate; a second electrode formed on the second surface side of the semiconductor substrate and electrically connected to the third region; a third electrode formed on a second surface side of the semiconductor substrate; a fourth electrode formed in the semiconductor substrate, reaching the second surface from the first surface, and electrically connecting the first region and the first electrode to each other; and a fifth electrode formed in the semiconductor substrate, reaching the second surface from the first surface, and electrically connecting the gate electrode and the third electrode to each other.

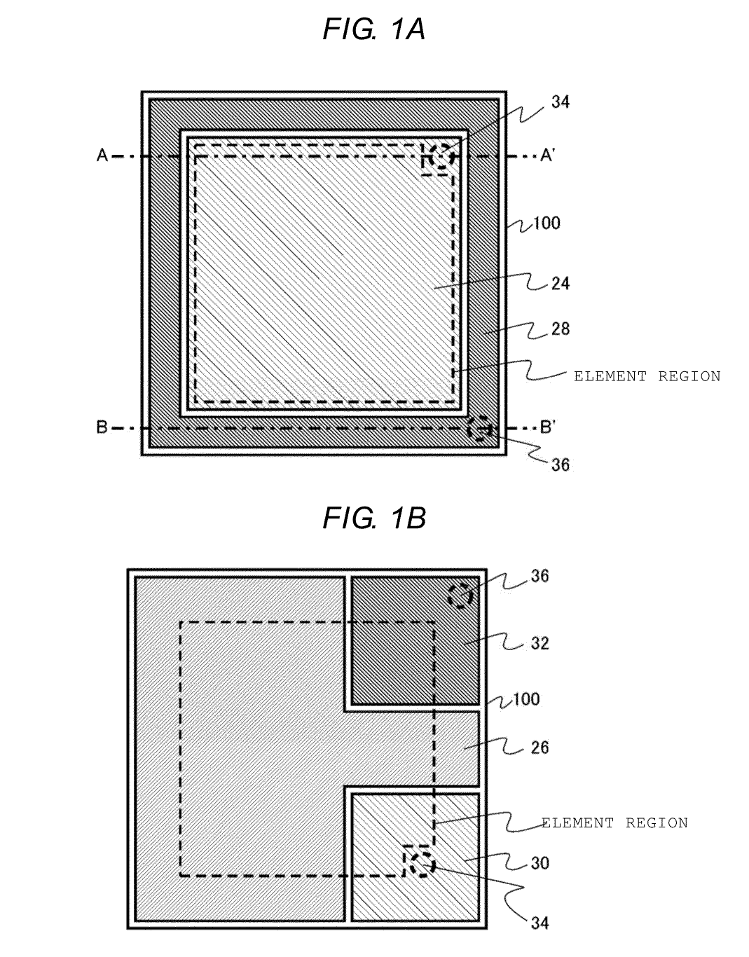

FIG. 1A and FIG. 1B are schematic plan views of a semiconductor device according to the first embodiment. FIG. 1A is a view showing an arrangement of electrodes and the like as viewed from a front surface side of the semiconductor device. FIG. 1B is a view showing an arrangement of the electrodes and the like as viewed from a back surface side of the semiconductor device. The back surface is opposite to the front surface.

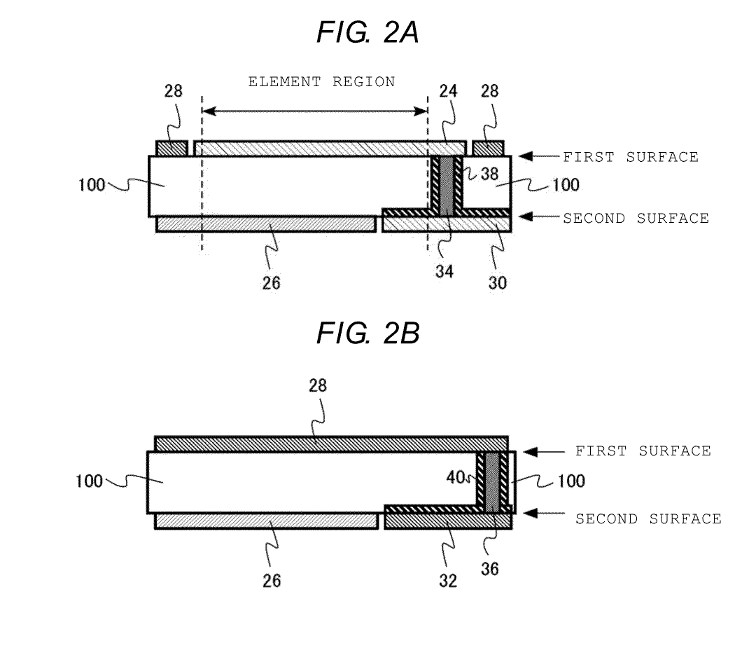

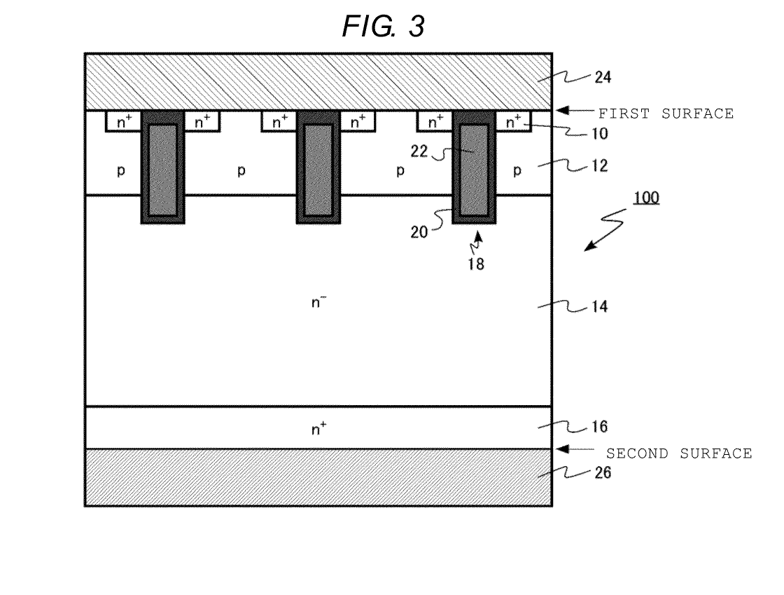

FIG. 2A and FIG. 2B are schematic cross-sectional views of FIG. 1A. FIG. 2A shows a cross section taken along a line A-A′ in FIG. 1A, and FIG. 2B shows a cross section taken along a line B-B′ in FIG. 1A. FIG. 3 is a schematic cross-sectional view of an element region of the semiconductor device according to the first embodiment.

The semiconductor device according to the first embodiment is a small signal MOSFET, for example. The semiconductor device according to the first embodiment is a vertical-type MOSFET where a source region and a drain region are provided with a semiconductor substrate interposed between the source region and the drain region. The semiconductor device according to the first embodiment is a trench-gate type MOSFET, where a gate electrode is disposed in a trench. A chip size of the small signal MOSFET is less than or equal to 1 mm×1 mm, for example.

As shown in FIG. 3, the semiconductor device according to the first embodiment includes a semiconductor substrate 100 having a first surface (hereinafter also referred to as the “front surface”) and a second surface (hereinafter also referred to as the “back surface”). The semiconductor substrate 100 is made of single crystal silicon, for example.

The semiconductor substrate 100 includes n⁺-type source regions (first regions) 10, a p-type channel region (second region) 12, an n⁻-type drift region (third region) 14, and an n⁺-type drain region 16.

The n⁺-type source regions 10 are formed at a front surface of the semiconductor substrate 100. The p-type channel region 12 is formed on a back surface side of the n⁺-type source regions 10. The n⁻-type drift region 14 is formed on a back surface side of the p-type channel region 12. The n⁺-type drain region 16 is formed at a back surface of the semiconductor substrate 100.

Trenches 18 are formed extending from a front surface of the semiconductor substrate 100. A gate insulation film 20 and a gate electrode 22 are formed in each trench 18. The gate insulation film 20 is disposed between the p-type channel region 12 and the gate electrode 22.

The gate insulation film 20 is formed of a silicon thermal oxidation film, for example. The gate electrode 22 is formed of polycrystalline silicon doped with an n-type dopant, for example.

A source electrode (sixth electrode) 24 is formed on a front surface side of the semiconductor substrate 100. The source electrode 24 is formed on the semiconductor substrate 100 in contact with the n⁺-type source regions 10. The source electrode 24 is electrically connected to the n⁺-type source regions 10. The source electrode 24 is made of metal. The source electrode 24 and the n⁺-type source regions 10 are in ohmic contact with each other.

A drain pad (second electrode) 26 is formed on a back surface side of the semiconductor substrate 100. The drain pad 26 is formed on the semiconductor substrate 100 in contact with the n⁺-type drain region 16. The drain pad 26 is made of metal. The drain pad 26 and the n⁺-type drain region 16 are in ohmic contact with each other. The drain pad 26 is connected to the n⁻-type drift region 14 via the n⁺-type drain region 16 interposed therebetween.

As shown in FIG. 1A, the source electrode (sixth electrode) 24 and a gate electrode line (seventh electrode) 28 are formed on the front surface side of the semiconductor substrate 100. The gate electrode line 28 is electrically connected to the gate electrodes 22 in an element region. The gate electrode line 28 surrounds the source electrode 24.

As shown in FIG. 1B, a source pad (first electrode) 30, a drain pad (second electrode) 26, and a gate pad (third electrode) 32 are formed on a back surface side of the semiconductor substrate 100. The source pad 30, the drain pad 26, and the gate pad 32 are formed such that a surface of the source pad 30, a surface of the drain pad 26, and a surface of the gate pad 32 on a side opposite to the semiconductor substrate 100 are substantially coplanar with each other. The source pad 30, the drain pad 26, and the gate pad 32 are made of metal.

As shown in FIG. 1B, a portion of the drain pad 26 is provided in a region between the source pad 30 and the gate pad 32.

In FIG. 1A and FIG. 1B, the element region area on the semiconductor substrate 100 is indicated by the area surrounded by a dotted line.

As shown in FIG. 2A, a first through-silicon-via (fourth electrode) 34, which reaches to a back surface from the front surface of the semiconductor substrate 100, is formed in the semiconductor substrate 100. The first through-silicon-via 34 penetrates the semiconductor substrate 100.

The first through-silicon-via 34 is made of metal. The first through-silicon-via 34 is made of copper (Cu) and is formed by an electroless plating method, for example. The first through-silicon-via 34 is insulated from the semiconductor substrate 100 by an insulation film 38.

The first through-silicon-via 34 electrically connects the source electrode 24 and the source pad 30 to each other. The source electrode 24 is electrically connected to the n⁺-type source regions 10. The first through-silicon-via 34 electrically connects the n⁺-type source regions 10 and the source pad 30 to each other.

As shown in FIG. 2B, a second through-silicon-via (fifth electrode) 36 which reaches the back surface from the front surface is formed in the semiconductor substrate 100. The second through-silicon-via 36 penetrates the semiconductor substrate 100.

The second through-silicon-via 36 is made of metal. The second through-silicon-via 36 is made of copper (Cu), and is formed by an electroless plating method, for example. The second through-silicon-via 36 is insulated from the semiconductor substrate 100 by an insulation film 40.

The second through-silicon-via 36 electrically connects the gate electrode line 28 and the gate pad 32 to each other. The gate electrode line 28 is electrically connected to the gate electrodes 22. The second through-silicon-via 36 electrically connects the gate electrodes 22 and the gate pad 32 to each other.

The element region is between the source pad 30 and the front surface of the semiconductor substrate 100. That is, the element region is formed in the semiconductor substrate 100 directly above the source pad 30. In other words, the n⁺-type source regions 10 are formed between the source pad 30 and the front surface of the semiconductor substrate 100.

The element region is also between the gate pad 32 and the front surface of the semiconductor substrate 100. That is, the element region is formed in the semiconductor substrate 100 directly above the gate pad 32. In other words, the n⁺-type source regions 10 are formed between the gate pad 32 and the front surface of the semiconductor substrate 100.

Next, the manner of operation and advantageous effects of the first embodiment is explained.

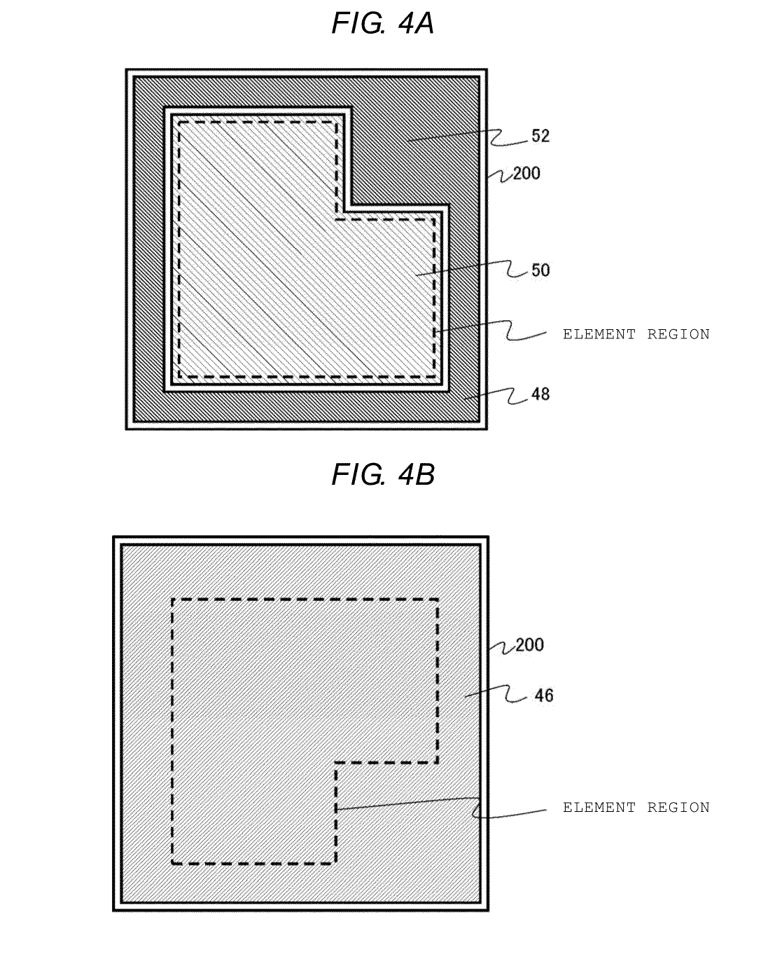

FIG. 4A and FIG. 4B are schematic plan views of a semiconductor device according to a comparison example. FIG. 4A is a view showing an arrangement of electrodes and the like as viewed from one surface (front surface) side of the semiconductor device. FIG. 4B is a view showing the arrangement of an electrode and the like as viewed from the other surface (back surface) side of the semiconductor device.

As shown in FIG. 4A, a source pad 50, a gate pad 52 and a gate electrode line 48 are formed on a front surface side of a semiconductor substrate 200. The source pad 50 is electrically connected to n⁺-type source regions 10, and the gate pad 52 is electrically connected to gate electrodes 22 through the gate electrode line 48.

As shown in FIG. 4B, a drain pad 46 is formed on a back surface side of the semiconductor substrate 200. The drain pad 46 is formed on the semiconductor substrate 200 in contact with an n⁺-type drain region 16 (not specifically depicted).

The source pad 50, the drain pad 46, and the gate pad 52 are made of metal.

In FIG. 4A and FIG. 4B, an area of the element region of the semiconductor substrate 200 is indicated by the area surrounded by the dotted line.

In a semiconductor device according to the comparison example, unlike the semiconductor device according to the first embodiment, the source pad 50 and the gate pad 52 are both formed on the front surface side of the semiconductor substrate 200. In the semiconductor device according to the comparison example, only the drain pad 46 is formed on the back surface side of the semiconductor substrate 200.

On the front surface side of the semiconductor substrate 200, the n⁺-type source regions 10 and the gate electrodes 22 are formed only in the element region. The source pad 50 which is connected to the n⁺-type source regions 10 is formed over the whole surface of the element region and hence, the gate pad 52 cannot be formed above the element region. In other words, it is difficult to form the element region on the semiconductor substrate 200 directly below the gate pad 52 because, by design, the source pad 50 occupies the entire surface of the element region. Accordingly, the element region is not formed below the gate pad 52, and regions of the semiconductor substrate 200 directly below the gate pad 52 become a dead space where the element region is not formed.

Because the portion of the semiconductor substrate 200 directly below the gate pad 52 becomes a dead space, it is difficult to reduce an ON resistance of a MOSFET switching device by increasing the percentage of the area that the element region occupies on the semiconductor substrate 200. Furthermore, in a device having a relatively small chip size such as a small signal MOSFET, the gate pad occupies a large portion of the total chip area and hence, this problem becomes conspicuous.

On the other hand, in the semiconductor device according to the first embodiment, as shown in FIG. 1A and FIG. 1B, the gate pad 32 is formed on the back surface side of the semiconductor substrate 100 using the second through-silicon-via 36. Accordingly, some portions of the element region may be provided between the gate pad 32 and the front surface of the semiconductor substrate 100 allowing for an increased total area of the element region without increasing the size of the semiconductor substrate 100. That is, portions of the element region may be provided on the semiconductor substrate 100 directly above the gate pad 32. Accordingly, an ON resistance of the MOSFET may be reduced by increasing the area that the element region occupies in the semiconductor substrate 100 rather than just by increasing the area (chip size) of the semiconductor substrate 100.

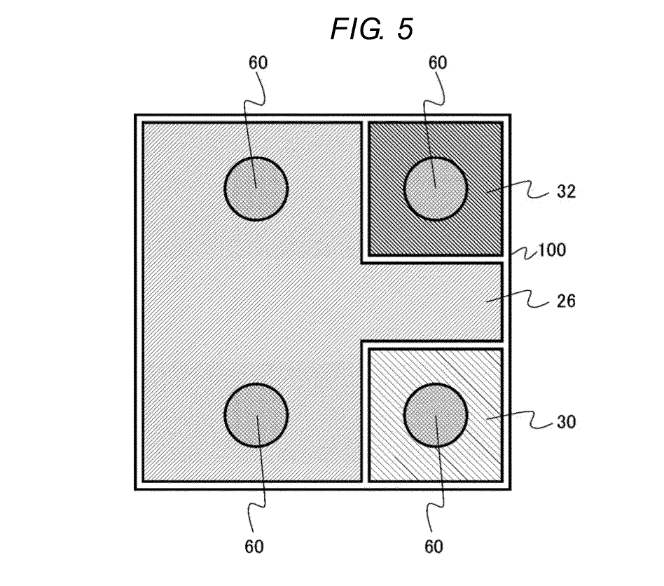

FIG. 5 is an explanatory view showing the manner of operation and advantageous effect of the semiconductor device according to the first embodiment. In the semiconductor device according to the first embodiment, the source pad 30, the drain pad 26, and the gate pad 32 are formed on the back surface side of the semiconductor substrate 100. Using the first through-silicon-via 34 and the second through-silicon-via 36 allows for the source pad 30 and the gate pad 32 to be placed on the back surface side of the semiconductor substrate 100.

Accordingly, as shown in FIG. 5, the semiconductor device of the first embodiment may be mounted as a WL-CSP (Wafer Level-Chip Size Package) having a BGA (Ball Grid Array) structure where solder balls 60 are formed on the source pad 30, the drain pad 26, and the gate pad 32, for example.

In the semiconductor device according to this first embodiment, as shown in FIG. 1B, the drain pad 26 is disposed in a region between the source pad 30 and the gate pad 32. The distance between the source pad 30 and the gate pad 32 is however relatively short, as such the portion of the n⁺-type drain region 16 in the element region between the source pad 30 and the gate pad 32 and above the drain pad 26 is correspondingly relatively small in the element region. Due to such structure, a parasitic resistance of the MOSFET is reduced so that the increase of the ON resistance may be suppressed.

As has been described above, according to the first embodiment, it is possible to form a vertical type MOSFET where an ON resistance may be reduced and a WL-CSP may be realized.

### Second Embodiment

A semiconductor device according to the second embodiment is similar to the semiconductor device of the first embodiment excepting that a first electrode (e.g., the source pad 30) or a third electrode (e.g., the gate pad 32) is surrounded by a second electrode (e.g., drain pad 26).

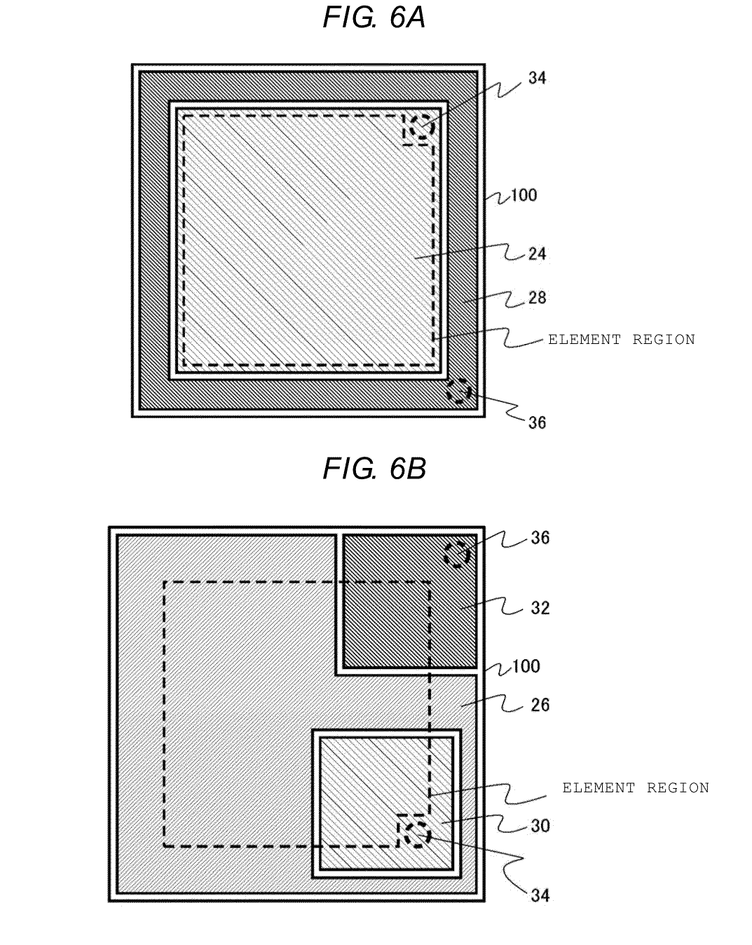

FIG. 6A and FIG. 6B are schematic plan views of the semiconductor device according to the second embodiment. FIG. 6A is a view showing an arrangement of electrodes and the like as viewed from one surface (front surface) side of the semiconductor device. Further, FIG. 6B is a view showing an arrangement of the electrodes and the like as viewed from the other surface (back surface) side of the semiconductor device.

As shown in FIG. 6B, a source pad (first electrode) 30 is arranged such that the source pad 30 is surrounded by a drain pad (second electrode) 26.

Due to such a configuration, the portion of the n⁺-type drain region 16 in the element region between the source pad 30 and the gate pad 32 can be reduced as compared to a corresponding portion of the n⁺-type drain region 16 in the first embodiment. Accordingly, a parasitic resistance of the MOSFET is further reduced so that the increase of the ON resistance may be further suppressed.

An embodiment where a gate pad (third electrode) 32 is surrounded by the drain pad (second electrode) 26 may also provide substantially the same advantageous effect.

As has been described above, according to the second embodiment, it is possible to forma vertical type MOSFET where an ON resistance may be further reduced and a WL-CSP may be realized.

In the example embodiments described above, the explanation has been made by taking the case where a first conductivity type is an n-type and a second conductivity type is a p-type as an example heretofore. However, it is also possible to adopt the configuration where a first conductivity type is a p-type and a second conductivity type is an n-type.

The explanation has been made by taking single crystal silicon as an example of a material for forming the semiconductor substrate in the example embodiments described above. However, other semiconductor materials such as silicon carbide or gallium nitride, for example, may instead be used as a material for forming the semiconductor substrate.

In the example embodiments described above, explanation has been made by taking a trench-gate type MOSFET as an example. However, the present invention is also applicable to a trench-gate type IGBT, a planar type MOSFET, a planar type IGBT or the like.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a semiconductor substrate having a first surface and a second surface opposite to the first surface and including:
a first region of a first conductivity type provided along the first surface,
a second region of a second conductivity type provided along the first surface, the first region being selectively provided in the second region, and
a third region of the first conductivity type between the second semiconductor region and the second surface;
a gate electrode adjacent to second region through a gate insulation film;
a first electrode pad on the second surface and electrically insulated from the third region;
a second electrode pad on the second surface and electrically connected to the third region;
a third electrode pad on the second surface and electrically insulated from the third region and electrically connected to the gate electrode;
a first via extending through the semiconductor substrate from the second surface to the first surface, a fourth electrode being in the first via and electrically connecting the first region to the first electrode pad; and
a second via extending through the semiconductor substrate from the second surface to the first surface, a fifth electrode being in the second via and electrically connecting the gate electrode to the third electrode pad.

2. The semiconductor device according to claim 1, wherein a first portion of the first region is between the first electrode pad and the first surface, and a second portion of the first region is between the third electrode pad and the first surface.

3. The semiconductor device according to claim 1, wherein a portion of the second electrode pad on the second surface is between the first electrode pad and the third electrode pad.

4. The semiconductor device according to claim 1, wherein the first electrode pad is surrounded by the second electrode on the second surface.

5. The semiconductor device according to claim 1, wherein the third electrode pad is surrounded by the second electrode pad on the second surface.

6. The semiconductor device according to claim 1, further comprising:
a source electrode on the first surface of the semiconductor substrate and electrically connected to the first region, the first electrode pad, and the fourth electrode.

7. The semiconductor device according to claim 6, further comprising:
a gate electrode line surrounding the source electrode on the first surface of the semiconductor substrate and electrically connected to the gate electrode, the third electrode pad, and the fifth electrode.

8. The semiconductor device according to claim 7, further comprising:
a plurality of gate electrodes, wherein a first portion of the plurality of gate electrodes is provided between the second electrode pad and the first surface in a direction substantially orthogonal to the first and second surfaces.

9. The semiconductor device according to claim 1, wherein an element region of the semiconductor substrate including the gate electrode and the first region is provided between the second electrode pad and the first surface in a direction substantially orthogonal to the first and second surfaces.

10. The semiconductor device according to claim 1, wherein an element region of the semiconductor substrate including the gate electrode and the first region is provided between the third electrode pad and the first surface in a direction substantially orthogonal to the first and second surfaces.

11. The semiconductor device according to claim 1, wherein the gate electrode is a portion of metal-oxide-semiconductor field-effect transistor (MOSFET).

12. The semiconductor device according to claim 1, wherein a solder ball is disposed on at least one of the first electrode pad, the second electrode pad, and the third electrode pad.

13. A semiconductor device, comprising:
a semiconductor substrate having a first surface and a second surface opposite to the first surface and including:
a drain contact region along the second surface;
a drift region on the drain region;
a channel region on the drift region; and
a source contact region along the first surface selectively between the channel region and the first surface;
a plurality of gate electrodes adjacent to channel region through a gate insulation film;
a source electrode on the first surface and electrically connected to the source contact region;
a gate electrode line on the first surface and electrically connected to the plurality of gate electrodes;
a source pad on the second surface, the source pad electrically insulated from the drain contact region and electrically connected through a first via to the source electrode, the first via extending through the semiconductor substrate from the first surface to the second surface;
a drain pad on the second surface and electrically connected to the drain contact region; and
a gate pad on the second surface, the gate pad electrically insulated from the drain contact region and electrically connected through a second via to the gate electrode line, the second via extending through the semiconductor substrate from the first surface to the second surface, wherein
a first portion of the plurality of gate electrodes is between the gate pad and the first surface along a first direction substantially orthogonal to the first surface.

14. The semiconductor device according to claim 13, wherein a second portion of the plurality of gate electrodes is between the source pad and the first surface along the first direction.

15. The semiconductor device according to claim 14, wherein a third portion of the plurality of gate electrodes is between the drain pad and the first surface along the first direction.

16. The semiconductor device according to claim 13, wherein the plurality of gate electrodes is disposed between the drain pad and the source electrode, the gate pad and the source electrode, and the source pad and the source electrode.

17. The semiconductor device according to claim 13, wherein the drain pad surrounds at least one of the source pad and the gate pad on the second surface.

18. The semiconductor device according to claim 13, wherein a portion of the drain pad on the second surface is between the source pad and the gate pad.

19. A semiconductor device, comprising:
a semiconductor substrate having a first surface and a second surface opposite to the first surface;
a source region in the semiconductor substrate and contacting the first surface;
a drain region in the semiconductor substrate and contacting the second surface;
a channel region in the semiconductor substrate between the source region and the drain region;
a gate electrode in the semiconductor substrate;
a gate insulation film between the gate electrode and the channel region;
a drain pad contacting the drain region at the second surface;
a source pad disposed on the second surface and electrically insulated from the drain region;
a gate pad disposed on the second surface and electrically insulated from the drain region;
a first via extending through the semiconductor substrate from the second surface to the first surface and electrically connected to the source region and the source pad; and
a second via extending through the semiconductor substrate from the second surface to the first surface and electrically connected to the gate electrode and the gate pad, wherein
a portion of the drain pad on the second surface is between the source pad and the gate pad, and
the gate electrode is between the gate pad and the source electrode.

20. The semiconductor device according to claim 19, wherein at least one of the source pad and the gate pad is surrounded on the second surface by the drain pad.
